(19) United States
(12) Patent Application Publication
(10) Pub. No.: US 2026/0045928 A1
(43) Pub. Date: Feb. 12, 2026

(54) BULK ACOUSTIC WAVE DEVICE WITH ENGINEERED REGIONS

(71) Applicant: Skyworks Global Pte. Ltd., Singapore (SG)

(72) Inventors: Kwang Jae Shin, Yongin-si (KR); Stefan Bader, Fort Collins, CO (US)

(21) Appl. No.: 19/291,427

(22) Filed: Aug. 5, 2025

Related U.S. Application Data
(60) Provisional application No. 63/680,299, filed on Aug. 7, 2024.

(51) Int. Cl. H03H 9/02; H03H 9/17; H03H 9/56

(52) U.S. Cl. CPC H03H 9/02015; H03H 9/173; H03H 9/568

(57) ABSTRACT

Aspects of this disclosure relate to a bulk acoustic wave that includes a piezoelectric layer positioned between electrodes. The piezoelectric layer includes a first region and a plurality of second regions. The plurality of second regions each have an effective piezoelectric coefficient with a lower magnitude than an effective piezoelectric coefficient of the first region. Related acoustic wave filters, multiplexers, radio frequency modules, radio frequency systems, wireless communication devices, methods of manufacture, and methods of filtering are disclosed.

### CROSS REFERENCE TO PRIORITY APPLICATION

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/680,299, filed Aug. 7, 2024 and titled “BULK ACOUSTIC WAVE DEVICE WITH ENGINEERED REGIONS,” the disclosures of which is hereby incorporated by reference in its entirety and for all purposes.

### BACKGROUND

### Technical Field

The disclosed technology relates to acoustic wave devices. Embodiments of this disclosure relate to bulk acoustic wave resonators with engineered regions.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) and dissipating heat in BAW devices is also generally desirable. There are technical challenges related to increasing Q, further suppressing spurious mode(s), and improving heat dissipation while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device that includes a first electrode, a second electrode, and a piezoelectric layer positioned between the first electrode and the second electrode. The piezoelectric layer includes a first region and a plurality of second regions. The plurality of second regions each have an effective piezoelectric coefficient with a lower magnitude than an effective piezoelectric coefficient of the first region.

The bulk acoustic wave device can include an acoustic reflector, where the first region and the plurality of second regions are over the acoustic reflector. The acoustic reflector can be a cavity.

The effective piezoelectric coefficient of each of the plurality of second regions can have has a magnitude that is less than 50% of a magnitude of the effective piezoelectric coefficient of the first region.

The plurality of second regions can include a first engineered region and a second engineered region that are separate and spaced apart by at least a portion of the first region. The second engineered region can have a ring shape in plan view. The first engineered region can have a solid cylindrical shape. The plurality of second regions can include a third engineered region having a ring shape in plan view, where the second engineered region is positioned between the first engineered region and the third engineered region. The ring shape can be a generally conformal transformation of a shape of an outer periphery of the bulk acoustic wave device. The first engineered region and the second engineered region can have prism shapes. The first engineered region can have an irregular shape. The first engineered region can have a shape that suppresses formation of a standing wave.

The plurality of second regions can have island shapes in plan view. The plurality of second regions can be periodically positioned. The plurality of second regions can have shapes that correspond to a contour of the bulk acoustic wave device. The plurality of second regions can be concentric in plan view. The plurality of second regions can include two to twenty second regions.

The bulk acoustic wave device can include a frame structure. The piezoelectric layer can have a peripheral region that vertically overlaps with the frame structure. The peripheral region can have an effective piezoelectric coefficient with a lower magnitude than the effective piezoelectric coefficient of the first region. The frame structure can includes a raised frame structure and/or a recessed frame structure.

Another aspect of this disclosure is bulk acoustic wave device having an acoustically active region, engineered regions, and a frame region. The bulk acoustic wave device includes a first electrode, a second electrode, a frame structure in the frame region, and a piezoelectric layer positioned between the first electrode and the second electrode. The piezoelectric layer has an effective piezoelectric coefficient in each of the engineered regions with a lower magnitude than an effective piezoelectric coefficient in the acoustically active region. The piezoelectric layer has an effective piezoelectric coefficient the frame region having a lower magnitude than the effective piezoelectric coefficient in the acoustically active region. The frame region surrounds the acoustically active region.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) device according to an embodiment.

FIG. 1B is a top plan view of a piezoelectric layer of the BAW device of FIG. 1A.

FIG. 1C is a cross-sectional side view of a BAW device structure that includes two BAW devices and an engineered piezoelectric layer between the two BAW devices according to an embodiment.

FIG. 2A is a schematic cross-sectional side view of a BAW device according to another embodiment.

FIG. 2B is a schematic top plan view of a piezoelectric layer of the BAW device of FIG. 2A.

FIG. 3 is a schematic top plan view of a piezoelectric layer of a BAW device according to an embodiment.

FIG. 4A is a schematic diagram of a ladder filter that includes one or more BAW resonators according to an embodiment.

FIG. 4B is schematic diagram of a band pass filter.

FIGS. 5A, 5B, 5C, and 5D are schematic diagrams of multiplexers that include a filter with one or more BAW resonators according to an embodiment.

FIGS. 6, 7, and 8 are schematic block diagrams of modules that include a filter with one or more BAW resonators according to an embodiment.

FIG. 9 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

Acoustic wave filters can filter radio frequency (RF) signals in a variety of applications, such as in an RF front end of a mobile phone. An acoustic wave filter can include bulk acoustic wave (BAW) devices. A film bulk acoustic wave resonator (FBAR) and a BAW solidly mounted resonator (SMR) are examples of BAW devices. BAW devices can generate heat during operation. Increasing the quality factor (Q) of a given BAW resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices can include frame structures, such as raised frame structures and/or recessed frame structures.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of layer that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a first electrode, a second electrode, and a piezoelectric layer positioned between the first and second electrodes. A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. However, a raised frame structure can create a resonance at a frequency that is below a resonant frequency of the main acoustically active region of the BAW device when the raised frame structure overlaps with the pair of electrodes and the piezoelectric layer over the acoustic reflector. This resonance can be below a main resonant frequency of the BAW device. A resonance associated with the raised frame structure can be referred to as a frame mode, and more specifically a raised frame mode. The raised frame mode can be undesirable in certain applications. At least a portion of the piezoelectric layer in the frame region can be engineered to suppress the frame mode.

Overheating can degrade the performance of the BAW devices and/or damage the BAW devices. Therefore, heat durability and/or sufficient heat dissipation can be significant for BAW devices. This disclosure provides technical solutions related to heat durability and/or heat dissipation in BAW devices. A piezoelectric layer can be engineered to have less acoustic activity in regions surrounded by at least part of a main acoustically active region. This can reduce a maximum temperature of the BAW device.

A BAW device can include a support substrate, a resonator including a first electrode, a second electrode, a piezoelectric layer between the first and second electrodes, and an acoustic reflector, such as air cavity, between the support substrate and the resonator. Heat is generated by the resonator during operation, and the heat can flow laterally through the piezoelectric layer. The piezoelectric layer can provide a heat dissipation path to a more thermally conductive element than the acoustic reflector to dissipate heat. For example, the piezoelectric layer can provide a heat dissipation path to the support substrate. However, absent compensation, a temperature at or near a center of the resonator can be significantly higher due to its heat dissipation path length. Therefore, an electrode of the resonator can be overheated at or near the center of the resonator. In some applications, a region that generates the most heat may not be the center of the resonator. In such applications, the region of the resonator that generates the most heat may be overheated.

An acoustic wave filter assembly, such as a filter, can include a plurality of acoustic wave devices. The shapes of each acoustic wave device in the filter can be a factor in arranging the acoustic wave devices in the filter. There may be unoccupied spaces in the filter due to the shapes of the acoustic wave devices, which can lead to increase in the filter size.

Embodiments of this disclosure relate to BAW devices (e.g., BAW resonators) that include a plurality of engineered region and a regular region of a piezoelectric layer. The regular region can be over an acoustic reflector and positioned between a pair of electrodes. The regular region can be the acoustically active region of a BAW device. The plurality of engineered regions can be regions of the piezoelectric layer and be laterally surrounded by at least a portion of the regular region of the piezoelectric layer. The plurality of engineered regions of the piezoelectric layer can have significantly less piezoelectric activity than the regular region, which can mitigate overheating in the BAW device and thereby improve heat durability. The plurality of engineered regions can have any suitable shape(s) and be arranged in any suitable manner. For example, one or more of the plurality of engineered regions can have a cylindrical shape, a ring shape, a prism shape (e.g., a polygonal prism or a star prism shape), or a shape that conforms to a shape of an outer periphery of the BAW device. In some embodiments, the plurality of engineered regions can be arranged in a manner that enables the BAW device to have a desired shape in a plan view.

In certain applications, having a capacitor in parallel with a BAW resonator can be advantageous. For example, a capacitor in parallel with a BAW resonator of a filter can improve the skirt performance and the insertion loss of the filter. This disclosure provides BAW devices that include a piezoelectric layer with engineered regions that can form an insulator of metal-insulator-metal capacitors that are in parallel with a BAW resonator.

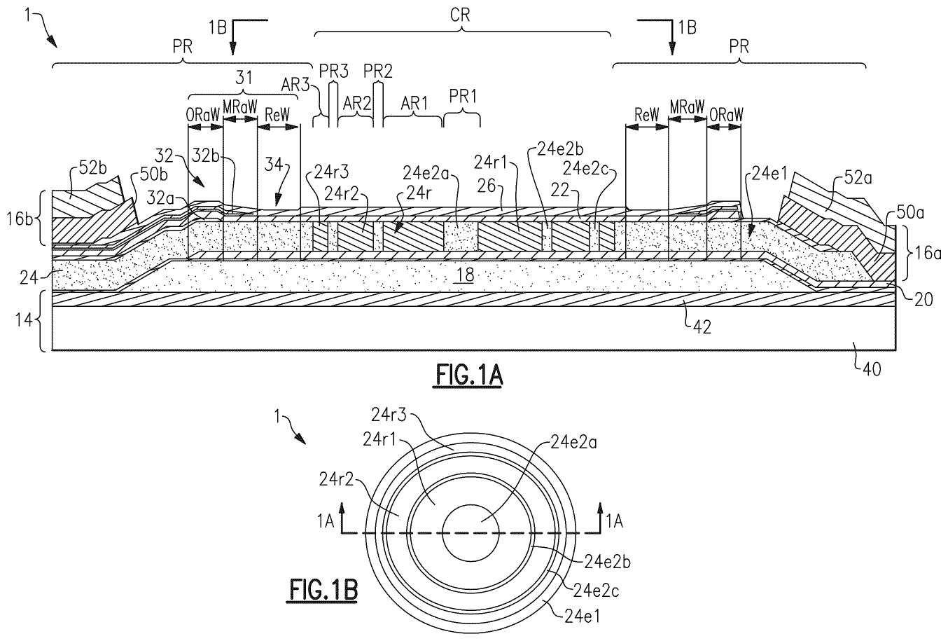

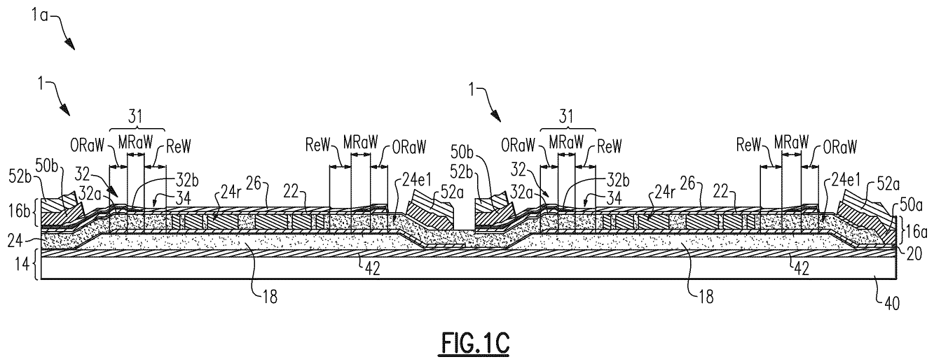

FIG. 1A is a schematic cross-sectional side view of a BAW device 1 according to an embodiment. FIG. 1B is a top plan view of a piezoelectric layer 24 of the BAW device 1 of FIG. 1A. The cross-section view of FIG. 1A is along the line 1A-1A in FIG. 1B.

Referring to FIG. 1A, the BAW device 1 has a central region CR and a peripheral region PR. The peripheral region PR can surround (e.g., laterally surround) the central region CR. The BAW device I can include an acoustic reflector (e.g., a cavity 18), a first electrode 20, a second electrode 22, and a piezoelectric layer 24. The piezoelectric layer 24 includes an engineered region 24e1 in the peripheral region PR and a plurality of engineered regions, (including engineered regions 24e2a, 24e2b, and 24e2c) in the central region CR. A region of the piezoelectric layer 24 that is not engineered can be referred to as a regular region 24r of the piezoelectric layer 24. The main acoustic activity of the BAW device 1 can occur in the regular region 24r of the piezoelectric layer 24. Accordingly, the regular region 24r can be referred to as the acoustically active region or as the main acoustically active region. A passivation layer 26 can be provided over the second electrode 22.

With the plurality of engineered regions 24e2a, 24e2b, and 24e2c in the central region CR of the BAW device, the BAW device 1 can have a lower maximum temperature during operation than a similar BAW device without the plurality of engineered regions 24e2a, 24e2b, and 24e2c in the central region CR. In some embodiments, the plurality of engineered regions can be arranged periodically.

The piezoelectric layer 24 can be positioned between (e.g., vertically between) the first electrode 20 and the second electrode 22. The regular region 24r, the engineered region 24e1 in the peripheral region PR, and the plurality of engineered regions 24e2a, 24e2b, and 24e2c in the central region CR can be laterally positioned relative to one another. In the illustrated embodiment, the plurality of engineered regions in the central region CR include a first engineered region 24e2a, a second engineered region 24e2b, and a third engineered region 24e2c. The regular region 24r can include a first regular region 24r1, a second regular region 24r2, and a third regular region 24r3.

The first engineered region 24e2a, the second engineered region 24e2b, and the third engineered region 24e2c can be spaced apart from each other by portions of the regular region 24r. For example, the first engineered region 24e2a can be spaced apart from the second engineered region 24e2b by the first regular region 24r1, the second engineered region 24e2b can be spaced apart from the third engineered region 24e2c by the second regular region 24r2, and the third engineered region 24e2c can be spaced apart from the engineered region 24e1 in the peripheral region PR by the third regular region 24r3.

As illustrated in FIG. 1B, the engineered regions 24e2a, 24e2b, and 24e2c are concentric. In some embodiments, the first engineered region 24e2a can have a cylindrical shape (e.g., a solid cylindrical shape), and the second engineered region 24e2b and the third engineered region 24e2c can have a ring shape (e.g., a circular ring shape). The second engineered region 24e2b and the third engineered region 24e2c can correspond to a countour of the bulk acoustic wave device 1. The second engineered region 24e2b can be positioned between the first engineered region 24e2a and the third engineered region 24e2c. The third engineered region 24e2c can have a greater diameter than the second engineered region 24e2b. The first engineered region 24e2a can be positioned at or near a center of the central region CR. In some embodiments, the BAW device 1 can have a circular shape in plan view, for example, as shown in FIG. 1B. In such embodiments, the ring shapes of the second and third engineered regions 24e2b, 24e2c may be a generally conformal transformation of the shape of the outer periphery of the BAW device 1. This can apply to any other suitable shapes of a BAW resonator in plan view.

A region where the first electrode 20, the second electrode 22, and the piezoelectric layer 24 overlap over the acoustic reflector (e.g., the cavity 18) and generate an acoustic wave can define an acoustically active region of the BAW device 1. The acoustically active region can include a first active region AR1, a second active region AR2, and a third active region AR3. The first electrode 20, the second electrode 22, and the regular region 24r of the piezoelectric layer 24 overlap over the acoustic reflector (e.g., the cavity 18) in the acoustically active region of the BAW device 1. The acoustically active region can be a main acoustically active region. The BAW device 1 can include a passive region including a first passive region PR1, a second passive region PR2, and a third passive region PR3. There can be little or no acoustic activity in the passive region. The first to third active regions AR1, AR2, AR3 and the first to third passive regions PR1, PR2, PR3 can be in the central region CR of the BAW device 1. The piezoelectric layer 24 in the first to third passive regions PR1, PR2, PR3 are engineered and the first to third engineered regions 24e2a, 24e2b, 24e2c, respectively, of the piezoelectric layer 24 have an effective piezoelectric coefficient with a lower magnitude than an effective piezoelectric coefficient of the regular region 24r of the piezoelectric layer 24 in the first to third active regions AR1, AR2, AR3.

The BAW device 1 can include a frame region outside of the main acoustically active region. The piezoelectric layer 24 in the frame region of the BAW device 1 is engineered. The piezoelectric layer 24 in the peripheral region PR of the BAW device 1 is engineered. The engineered region 24e1 of the piezoelectric layer 24 has an effective piezoelectric coefficient with a lower magnitude than an effective piezoelectric coefficient of the regular region 24r of the piezoelectric layer 24 in the first to third active regions AR1, AR2, AR3, respectively. The frame region and the peripheral region PR can at least partially overlap. The frame region can include a raised frame region and a recessed frame region. In some embodiments, a recessed frame portion of the frame region can partially overlap the third active region AR3. In such embodiments, a region of the third active region AR3 that does not overlap the frame region can be the main acoustically active region.

During operation of the BAW device 1, heat can be generated in the acoustically active region (e.g., the first to third active regions AR1, AR2, AR3). The heat generated in the first to third active regions AR1, AR2, AR3 can be transferred through the piezoelectric layer 24 to other portions of the BAW device 1. For example, the heat can be transferred through the piezoelectric layer 24 to a support structure 14 where the cavity 18 is not positioned between the piezoelectric layer 24 and the support structure 14. The passive regions PR1, PR2, PR3 that include the first to third engineered regions 24e2a, 24e2b, 24e2c can function as cooling structures. The engineered region in the central region CR can reduce heat generation in the central region CR of the BAW device 1 by reducing or eliminating acoustic activity in the passive regions PR1, PR2, PR3. This can provide improved power handling and ruggedness for the BAW device 1. The locations of the passive regions PR1, PR2, PR3 are located can be determined based at least in part on locations of the acoustically active region (e.g., the first to third active regions AR1, AR2, AR3) that generate more heat absent the passive regions PR1, PR2, PR3. This may not be the exact center of the acoustically active region in some applications.

As shown in FIG. 1B, a shape of the first engineered region 24e2a in a plan view can conform to a shape of the BAW device 1 and shapes of the second and third engineered regions 24e2b, 24e2c in a plan view can conform to a shape of an outer periphery of the BAW device 1, in some embodiments. The first to third engineered regions 24e2a, 24e2b, 24e2c in a plan view can have any other suitable shape(s), such as a polygonal shape, an elliptical shape, a star shape, or an irregular shape, in some other embodiments. The irregular shape can prevent or suppress formation of a standing wave in the BAW device 1.

The BAW device 1 can include a frame structure 31 in the frame region. The frame structure 31 can include a raised frame structure 32 and/or a recessed frame structure 34. The recessed frame structure 34 can be positioned in the central region CR or be positioned in the peripheral region PR that is outside of the central region CR. In some embodiments, a mass loading structure (not shown) can be provided in the passive regions PR1, PR2, PR3. The mass loading structure can include a raised structure, such as a metal raised structure. The mass loading structure can further suppress a piezoelectric effect in the passive regions PR1, PR2, PR3. The first to third engineered regions 24e2a, 24e2b, 24e2c can suppress an unwanted mode caused by the mass loading structure in the passive region MR.

The engineered regions 24e1, 24e2a, 24e2b, and 24e2c of the piezoelectric layer 24 can have a lower magnitude effective piezoelectric coefficient than the regular region 24r of the piezoelectric layer 24. For example, the engineered regions 24c1, 24e2a, 24e2b, and 24e2c of the piezoelectric layer 24 can have an effective piezoelectric coefficient magnitude that is less than 50% of the magnitude of effective piezoelectric coefficient of the regular region 24r of the piezoelectric layer 24. As another example, the engineered regions 24e1, 24e2a, 24e2b, and 24e2c of the piezoelectric layer 24 can have an effective piezoelectric coefficient magnitude that is less than 20% of the effective piezoelectric coefficient magnitude of the regular region 24r of the piezoelectric layer 24 in the acoustically active region AR. As one more example, the engineered regions 24e1, 24e2a, 24e2b, and 24e2c of the piezoelectric layer 24 can have an effective piezoelectric coefficient magnitude that is less than 10% of the effective piezoelectric coefficient magnitude of the regular region 24r of the piezoelectric layer 24 in the acoustically active region AR. Even though the engineered regions 24e1, 24e2a, 24e2b, and 24e2c may have little or no piezoelectricity, the engineered regions 24e1, 24e2a, 24e2b, and 24e2c can be considered parts of the piezoelectric layer 24 of BAW devices of this disclosure.

In some embodiments, the engineered regions 24e1, 24e2a, 24e2b, and 24e2c can be dielectric and the engineered regions 24e1, 24e2a, 24e2b, and 24e2c and portions of the first and second electrodes 20, 22 can form metal-insulator-metal (MIM) capacitors. The BAW device 1 can include MIM capacitors in parallel with a BAW resonator. The MIM capacitors can include the engineered regions 24e2a, 24e2b, and 24e2c of the piezoelectric layer 24 as a respective insulator and overlapping portions of the first electrode 20 and the second electrode 22. The MIM capacitors can increase the steepness of a skirt of a filter that includes the BAW device 1 and/or reduce insertion loss of the filter.

The effective piezoelectric coefficient of the engineered region 24e1 in the peripheral region PR can be an aggregate piezoelectric coefficient for the entire engineered region 24e1. The aggregate magnitude of the piezoelectric polarization vectors in the engineered region 24e1 should be less than the magnitude in the regular region 24r. The lower magnitude effective piezoelectric coefficient can be a result of the non-aligned nature of piezoelectric material crystal orientations within the engineered region 24e1 causing a lower aggregate magnitude of the piezoelectric polarization vectors. The effective piezoelectric coefficient of each of the engineered regions 24e2a, 24e2b, and 24e2c in the passive regions PR1, PR2, PR3 region PR can be a respective aggregate piezoelectric coefficient for the entire engineered region 24e2a, 24e2b, or 24e2c. The aggregate magnitude of the piezoelectric polarization vectors in each of the engineered regions 24e2a, 24e2b, 24e2c should be less than the magnitude in the regular region 24r. The lower magnitude effective piezoelectric coefficient can be a result of the non-aligned nature of piezoelectric material crystal orientations within the engineered regions 24e2a, 24e2b, 24e2c causing a lower aggregate magnitude of the piezoelectric polarization vectors.

The effective piezoelectric coefficient can be an effective piezoelectric coupling coefficient (e₃₃), for example. The engineered region 24e1 of the piezoelectric layer 24 in the peripheral region PR can suppress the frame mode associated with the raised frame structure 32. The engineered region 24e1 of the piezoelectric layer 24 can suppress the frame mode associated with the recessed frame structure 34. BAW devices with an engineered region (e.g., the engineered region 24e1) of a piezoelectric layer vertically overlapping with a frame structure (e.g., a raised frame structure 32 and/or a recessed frame structure 34) disclosed herein can enable frame mode suppression, transverse mode suppression, and lateral mode suppression. At the same time, such BAW devices can achieve desirable quality factor (Q) values.

A boundary or border between the regular region 24r and the engineered region 24e1 of the piezoelectric layer 24 can be the boundary or border between the active region AR (e.g., the third active region AR3) and the peripheral region PR. The border between the regular region 24r and the engineered region 24e1 can be adjusted to have more engineered region area +EPA or less engineered region area −EPA relative to the BAW device 1 shown in FIG. 1A. A boundary or border between the regular region 24r and the first to third engineered regions 24e2a, 24e2b, 24e2c of the piezoelectric layer 24 can be the boundary or border between the active region AR and the corresponding passive regions PR1, PR2, PR3.

A seed layer can be positioned between the first electrode 20 and the engineered regions 24e2a, 24e2b, 24e2c of the piezoelectric layer 24. The seed layer can cause the piezoelectric layer 24 to be engineered in the engineered regions 24e2a, 24e2b, 24e2c. The seed layer can be a material that has poor crystallinity or is crystalline with a poor lattice match to the piezoelectric film applied over the seed layer. The piezoelectric layer 24 in the engineered regions 24e2a, 24e2b, 24e2c over the seed layer can have relatively poor bulk piezoelectric properties compared to the piezoelectric layer in the regular region 24r. The seed layer can be directly over the first electrode 20. The seed layer can be an atomic deposition layer, for example. The seed layer can include, but is not limited to, an oxide, a nitride, a carbide, a carbon structure (e.g., graphene or diamond), a boride, or any suitable combination thereof. In certain applications, the seed layer can include one or more of aluminum oxide, silicon, silicon carbide, doped aluminum nitride, undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In some embodiments, the seed layer can have a thickness that is in a single digit nanometer range. In some embodiments, the seed layer can have a thickness that is in a range from 10 nanometers to 100 nanometers.

In some embodiments, a uniform piezoelectric material can be deposited and then the engineered regions 24e2a, 24e2b, 24e2c of the piezoelectric material can be modified to be less piezoelectric than the regular regions 24r1, 24r2, 24r3. For example, ions can be implanted to modify the structure and properties of the piezoelectric material by ion implantation to form the engineered regions 24e2a, 24e2b, 24e2c. In such embodiments, the piezoelectric material can be engineered from a side opposite the first electrode 20.

Referring to FIG. 1A, the first electrode 20 can be referred to as a lower electrode. The first electrode 20 can have a relatively high acoustic impedance. The first electrode 20 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 20 in certain applications. The second electrode 22 can be referred to as an upper electrode. The thickness of the first electrode 20 can be approximately the same as the thickness of the second electrode 22 in the acoustically active region AR of the BAW device 1.

The piezoelectric layer 24 can include a suitable material such as, but not limited to, aluminum nitride (AIN), zinc oxide (ZnO), or lead zirconium titanate (PZT). In certain applications, the piezoelectric layer 24 can be an AIN layer. The piezoelectric material can be doped or undoped. For example, an AlN-based piezoelectric layer can be doped with any suitable dopant, such as scandium (Sc), chromium (Cr), magnesium (Mg), sulfur(S), yttrium (Y), silicon (Si), germanium (Ge), oxygen (O), hafnium (Hf), zirconium (Zr), titanium (Ti), tantalum (Ta), boron (B), niobium (Nb), or the like. In certain applications, the piezoelectric layer 24 can be AIN based layer doped with Sc. Doping the piezoelectric layer 24 can change the resonant frequency. When an AIN piezoelectric layer is doped with Sc, the resonant frequency of a given stack can be decreased. Doping the piezoelectric layer 24 can increase the electromechanical coupling coefficient (kt²) of the BAW device 1. Doping to increase the kt² can be advantageous at higher frequencies where kt² can be degraded. In certain applications, two or more piezoelectric layers can be implemented with any suitable principles and advantages disclosed herein.

The frame structure 31 can be configured to suppress the transverse mode. The raised frame structure 32 can reduce or impede propagation of transverse mode. As illustrated, the raised frame structure 32 is a multi-layer raised frame structure that includes a raised frame structure 32a and a raised frame structure 32b. The raised frame structure 32b can include a material that has a relatively high mass density. For instance, the raised frame structure 32b can include molybdenum (Mo), tungsten (W), ruthenium (Ru), the like, or any suitable alloy thereof. In some embodiments, the raised frame structure 32b and the second electrode 22 can be formed of a same material. The raised frame structure 32b can be a metal layer. Alternatively, the raised frame structure 32b can be a suitable non-metal material with a relatively high density. The density of the raised frame structure 32b can be similar to or heavier than the density of the first electrode 20 or the second electrode 22. The raised frame structure 32a can include a low acoustic impedance material that has a lower acoustic impedance than the first electrode 20, the second electrode 22, and/or the piezoelectric layer 24. For example, the raised frame structure 32a can include a silicon dioxide (SiO₂) layer, a silicon nitride (SiN) layer, a silicon carbide (SiC) layer, or any other suitable low acoustic impedance layer. The raised frame structure 32a can be a dielectric layer. The raised frame structure 32a can be an oxide layer. For example, the raised frame structure 32 shown in FIG. 1A includes an oxide raised frame structure 32a having a width ORaW, and a metal raised frame structure 32b having a width MRaW between the recessed frame structure 34 and the oxide raised frame structure 32a.

A frame structure can include, for example, a single layer raised frame structure, a multi-layer raised frame structure that includes two or more raised frame layers such as the illustrated raised frame structure 32, a recessed frame structure such as the illustrated recessed frame structure 34, or a combination of a raised frame structure and a recessed frame structure such as the illustrated frame structure 31. As an example, a frame structure can have a multi-layer raised frame structure that includes a relatively high density layer and a relatively low acoustic impedance layer. The low acoustic impedance layer can contribute to reducing an effective electromechanical coupling coefficient (kt²) relative to a single high-density raised frame structure, which can reduce excitation strength of a raised frame spurious mode. As another example, a floating raised frame structure can be implemented. In the BAW device 1, the frame structure 31 is illustrated as being asymmetric about the central region CR. However, in some embodiments, the frame structure 31 can be symmetric about the central region CR.

The support structure 14 can include a support substrate 40 and an intermediate layer 42 between the support substrate and the first electrode 20. The support substrate 40 can be a semiconductor substrate. The support substrate 40 can be a silicon substrate. The support substrate 40 can be any other suitable support substrate, such as a substrate of quartz, silicon carbide, sapphire, glass, gallium arsenide, or any suitable ceramic (e.g., spinel, alumina, etc.).

The intermediate layer 42 can include, for example, one or more of a seed layer, a trap rich layer, a passivation layer, or one or more other suitable functional layers. In some embodiments, the intermediate layer 42 can be completely or partially omitted. In some such embodiments, a portion of the first electrode 20 can directly contact the support substrate 40. The intermediate layer 42 can be relatively thin. For example, the intermediate layer 42 can be significantly thinner than the support substrate 40. Heat generated by the BAW device 1 can dissipate through the first electrode 20 to the support substrate 40 at a location where there is no cavity 18 between the first electrode 20 and the support substrate 40.

As shown in FIG. 1A, a first interconnect structure 16a can include one or more conductive layers such as a first conductive layer 50a and a second conductive layer 52a. Similarly, a second interconnect structure 16b can include one or more conductive layers such as a first conductive layer 50b and a second conductive layer 52b. The first conductive layers 50a, 50b and the second conductive layers 52a, 52b can each include a material suitable for interconnecting the BAW device 1 and one or more other components (e.g., another resonator) in a filter, an external component, or a ground connection. The first conductive layers 50a, 50b and/or the second conductive layers 52a, 52b can be highly conductive. For example, the first conductive layers 50a, 50b and/or the second conductive layers 52a, 52b can be more electrically conductive than the first electrode 20 and/or the second electrode 22. In some embodiments, the first conductive layers 50a, 50b and/or the second conductive layers 52a, 52b can include one or more of gold (Au), titanium (Ti), copper (Cu), aluminum (Al), or tungsten (W).

The cavity 18 (e.g., an air cavity) can be formed between the support substrate 40 and the first electrode 20. Heat generated by the piezoelectric layer 24 can flow laterally over the cavity 18 to a heat dissipation path where the BAW device 18 is free from the cavity 18 between the piezoelectric layer 23 and the support structure 14. The cavity 18 is an example of an acoustic reflector. The BAW device 1 can include an FBAR. In some other embodiments, there can be a solid acoustic mirror in place of the cavity 18 and such a BAW device can be a BAW SMR.

An additional heat dissipation path can be included in a BAW device to further improve heat dissipation in the BAW device. For example, a thermally conductive structure (not shown), such as a thermally conductive pillar, can be provided between one or more of the engineered regions 24e2a, 24e2b, and 24e2c and the support structure 14 to provide a heat path therebetween. For instance, a thermally conductive pillar can be included between the engineered region 24e2a and the support structure 14.

The engineered region 24e1 can extend outside of the BAW device 1 between different resonators to reduce crosstalk between different resonators, in some embodiments. For example, the engineered region 24e1 between different resonators can prevent or mitigate a wave or resonance generated in one resonator from reaching an adjacent resonator. Mitigating crosstalk between resonators can be more significant when resonators are closer together to make filters smaller. A no collar process in conjunction with a flat cavity may be utilized with the engineered region 24e1 outside of the BAW device 1 for reducing or eliminating cross talk between BAW devices.

FIG. 1C is a cross-sectional side view of a BAW device structure la according to an embodiment. Unless otherwise noted, the components of the BAW device structure 1a shown in FIG. 1C may be structurally and/or functionally the same as or generally similar to like components of other BAW devices disclosed herein. The BAW device structure la can include two similar or identical BAW devices 1. In some other applications, the BAW device structure la may include two or more non-identical BAW devices. The engineered region 24e1 between the two BAW devices 1 can reduce coupling (e.g., capacitive coupling through the piezoelectric layer) between the two BAW devices 1. According to some embodiments, an electrode of one BAW device 1 can be electrically connected to an electrode of another BAW device 1 over the engineered region 24e1 between the two BAW devices 1.

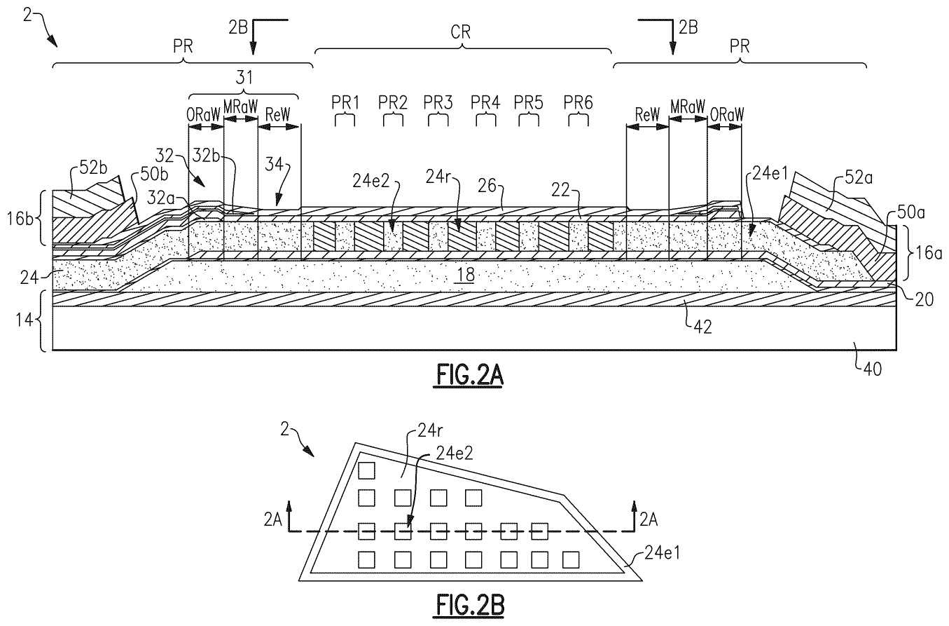

A BAW device can have any suitable shape in a top plan view. Also, the BAW device can have any suitable number of engineered regions of any suitable shape in a central region arranged in any suitable manner. For example, in some applications, a BAW device can have a number of engineered regions in a range from 2 to 20. FIGS. 2A-3 show BAW devices that include a plurality of engineered regions in a central region according to various embodiments.

FIG. 2A is a schematic cross-sectional side view of a BAW device 2 according to an embodiment. FIG. 2B is a schematic top plan view of the piezoelectric layer 24 of the BAW device 2. The cross-section view of FIG. 2A is along the line 2A-2A in FIG. 2B. Unless otherwise noted, the components of the BAW device 2 shown in FIGS. 2A and 2B may be structurally and/or functionally the same as or generally similar to like components of other BAW devices disclosed herein.

The piezoelectric layer 24 of the BAW device 2 has a different top plan view from the piezoelectric layer 24 of the BAW device 1. Also, the BAW device 2 has a different number of engineered regions having a different shape from the engineered regions of the BAW device 1. Unlike the circular top plan view shape of the BAW device 1, the BAW device 2 has a quadrilateral top plan view shape. In the BAW device 2, the plurality of engineered regions 24e2 of the piezoelectric layer 24 in the central region CR can be referred to as a plurality of engineered islands (e.g., eighteen engineered islands as illustrated in FIG. 2B). The regions of the BAW device 2 where the plurality of engineered islands are located can be referred to as passive regions. In FIG. 2A, six passive regions PR1, PR2, PR3, PR4, PR5, and PR6 that correspond to six islands of the plurality of engineered regions 24e2 are illustrated. Each of the engineered regions 24e2 can be surrounded by different portions of the regular region 24r. Although there are eighteen engineered islands in the piezoelectric layer 24 illustrated in FIG. 2B, any suitable number of engineered islands in a piezoelectric layer 24 can be used in the BAW device 2.

During operation of the BAW device 2, heat can be generated in the acoustically active region. The heat generated in the acoustically active region can be transferred through the piezoelectric layer 24 to other portions of the BAW device 2. For example, the heat can be transferred through the piezoelectric layer 24 to a support structure 14 where the cavity 18 is not positioned between the piezoelectric layer 24 and the support structure 14. The passive regions that include the plurality of engineered regions 24e2 can function as a cooling structure. The engineered regions 24e2 in the central region CR can reduce heat generation in the central region CR of the BAW device 1 by reducing or eliminating acoustic activity in the passive regions PR1-PR6. This can provide improved power handling and ruggedness. The location of the passive regions where the plurality of engineered regions 24e2 are located can be determined based at least in part on locations of the acoustically active region AR that generate more heat absent the passive regions. This may not be the exact center of the acoustically active region AR in some applications. The shape of the plurality of engineered regions 24e2 is not limited to those shown in FIG. 2B.

FIG. 3 is a schematic top plan view of a piezoelectric layer of a BAW device 3 according to an embodiment. Unless otherwise noted, the components of the BAW device 3 shown in FIG. 3 may be structurally and/or functionally the same as or generally similar to like components of other BAW devices disclosed herein. The BAW device 3 can include a regular region 24r of a piezoelectric layer in an acoustically active region, an engineered region 24e1 in a peripheral region, and engineered region 24e2 in a central region. The engineered region 24e2 can be referred to as a plurality of engineered islands. The plurality of engineered islands can each have a star shape in the plan view. Any other suitable shape of engineered regions of the piezoelectric layer can alternatively or additionally be implemented. Any suitable number of the plurality of engineered islands can be included in the BAW device 3.

BAW devices disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, base stations, repeaters, relays, wireless communication infrastructure, access points, customer premises equipment (CPE), and distributed antenna systems. BAW oscillators can replace crystal oscillators in a variety of applications, such as but not limited to electronic timing products.

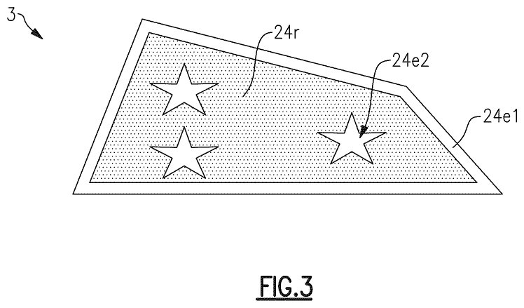

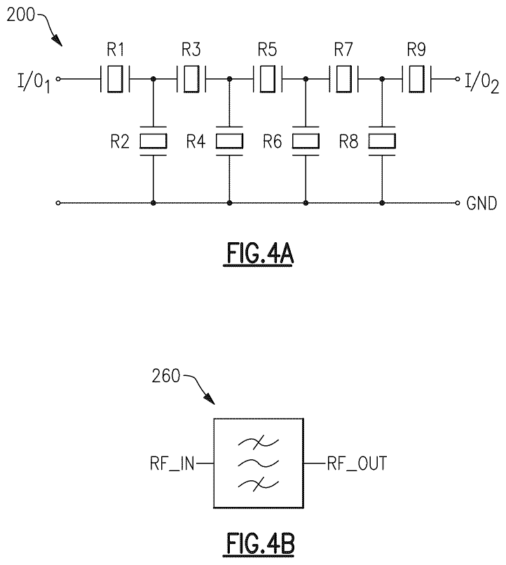

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 4A.

FIG. 4A is a schematic diagram of a ladder filter 200 that includes an acoustic wave resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein can be arranged to filter a radio frequency signal in any other suitable operating band, such as a WiFi operating band, a Global Positioning System (GPS) operating band, a Bluetooth operating band, a ZigBee operating band, a WiMax operating band, etc.

The BAW resonators disclosed herein can be advantageous for implementing BAW devices with relatively high Qp, relatively low spur intensity, and desirable heat dissipation. Such BAW resonators can have desirable power handling and ruggedness characteristics BAW resonators disclosed herein can have significantly better performance than a variety of other BAW resonators. This can be advantageous in meeting demanding specifications for acoustic wave filters, such as performance specifications for certain 5G applications.

FIG. 4B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

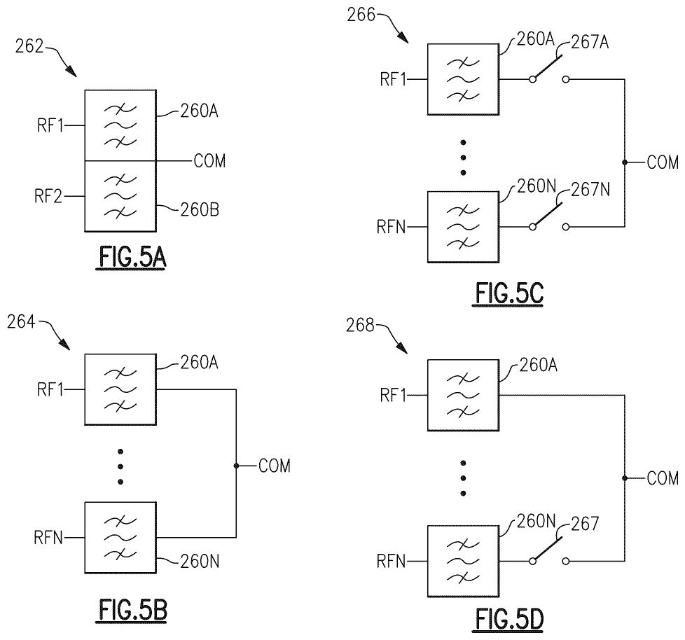

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 5A to 5D. Any suitable principles and advantages of these multiplexers can be implemented together with each other.

FIG. 5A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 5B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 5C is a schematic diagram of a multiplexer 266 that includes an acoustic wave filter according to an embodiment. The multiplexer 266 is like the multiplexer 264 of FIG. 5B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 5D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

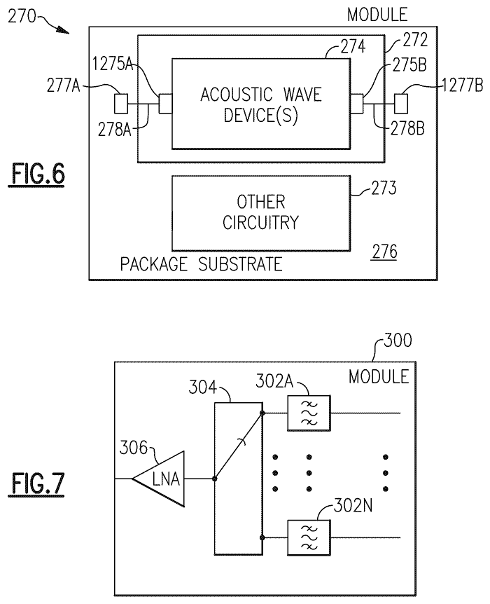

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 6, 7, and 8 are schematic block diagrams of illustrative packaged modules according to certain embodiments. Any suitable combination of features of these packaged modules can be implemented with each other.

FIG. 6 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 6 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 6. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 7 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

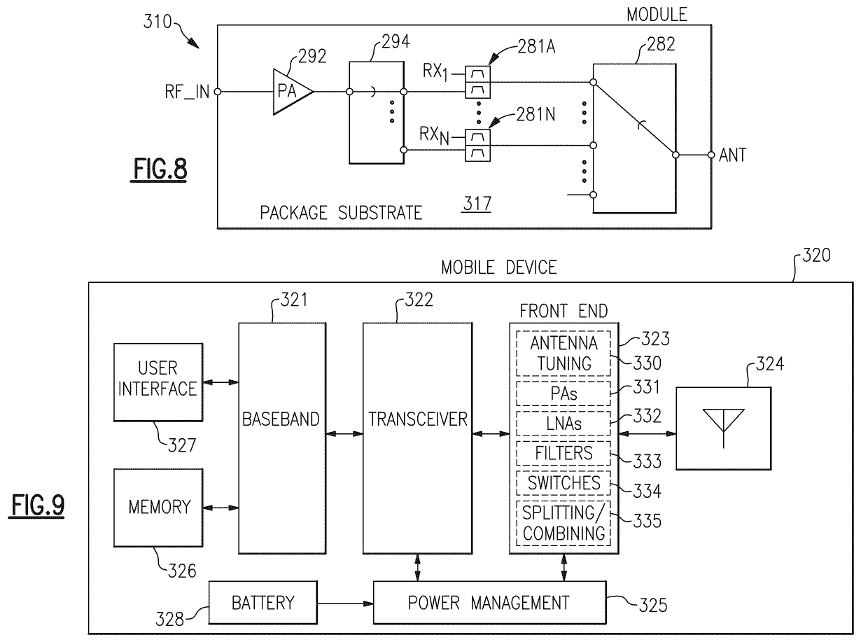

FIG. 8 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 8 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The BAW devices disclosed herein can be implemented in wireless communication devices. FIG. 9 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 9 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 9, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 9, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device comprising:
a first electrode;
a second electrode; and
a piezoelectric layer positioned between the first electrode and the second electrode, the piezoelectric layer including a first region and a plurality of second regions, the plurality of second regions each having an effective piezoelectric coefficient with a lower magnitude than an effective piezoelectric coefficient of the first region.

2. The bulk acoustic wave device of claim 1 further comprising an acoustic reflector, the first region being over the acoustic reflector, and the plurality of second regions being over the acoustic reflector.

3. The bulk acoustic wave device of claim 2 wherein the acoustic reflector is a cavity.

4. The bulk acoustic wave device of claim 1 wherein the effective piezoelectric coefficient of each of the plurality of second regions has a magnitude that is less than 50% of a magnitude of the effective piezoelectric coefficient of the first region.

5. The bulk acoustic wave device of claim 1 wherein the plurality of second regions include a first engineered region and a second engineered region that are separate and spaced apart by at least a portion of the first region.

6. The bulk acoustic wave device of claim 5 wherein the second engineered region has a ring shape in plan view.

7. The bulk acoustic wave device of claim 6 wherein the first engineered region has a solid cylindrical shape.

8. The bulk acoustic wave device of claim 6 wherein the plurality of second regions further includes a third engineered region having a ring shape in plan view, the second engineered region positioned between the first engineered region and the third engineered region.

9. The bulk acoustic wave device of claim 5 wherein the first engineered region and the second engineered region have prism shapes.

10. The bulk acoustic wave device of claim 5 wherein the first engineered region has an irregular shape.

11. The bulk acoustic wave device of claim 5 wherein the first engineered region has a shape that suppresses formation of a standing wave.

12. The bulk acoustic wave device of claim 1 wherein the plurality of second regions have island shapes in plan view.

13. The bulk acoustic wave device of claim 1 wherein the plurality of second regions are periodically positioned.

14. The bulk acoustic wave device of claim 1 wherein the plurality of second regions have shapes that correspond to a contour of the bulk acoustic wave device.

15. The bulk acoustic wave device of claim 1 wherein the plurality of second regions are concentric in plan view.

16. The bulk acoustic wave device of claim 1 further comprising a frame structure, the piezoelectric layer having a peripheral region that vertically overlaps with the frame structure, the peripheral region having an effective piezoelectric coefficient with a lower magnitude than the effective piezoelectric coefficient of the first region.

17. The bulk acoustic wave device of claim 16 wherein the frame structure includes a raised frame structure and a recessed frame structure.

18. The bulk acoustic wave device of claim 16 wherein the frame structure includes a raised frame structure.

19. A bulk acoustic wave device having an acoustically active region, engineered regions, and a frame region, the bulk acoustic wave device comprising:
a first electrode;
a second electrode;
a frame structure in the frame region, the frame region surrounding the acoustically active region and the engineered regions; and
a piezoelectric layer positioned between the first electrode and the second electrode, the piezoelectric layer having an effective piezoelectric coefficient in each of the engineered regions with a lower magnitude than an effective piezoelectric coefficient in the acoustically active region, and the piezoelectric layer having an effective piezoelectric coefficient the frame region having a lower magnitude than the effective piezoelectric coefficient in the acoustically active region.

20. An acoustic wave filter for filtering a radio frequency signal, the acoustic wave filter comprising:
a bulk acoustic wave resonator including a first electrode, a second electrode, and a piezoelectric layer positioned between the first electrode and the second electrode, the piezoelectric layer including a first region and a plurality of second regions, the plurality of second regions each having an effective piezoelectric coefficient with a lower magnitude than an effective piezoelectric coefficient of the first region; and
a plurality of additional acoustic wave resonators, the bulk acoustic wave resonator and the plurality of additional acoustic wave resonators configured to filter the radio frequency signal.
